(19) United States
(12) Patent Application Publication
(10) Pub. No.: US 2014/0375334 A1
(43) Pub. Date: Dec. 25, 2014

(54) SYSTEMS AND METHODS FOR SELECTING CIRCUIT ELEMENT VALUES FOR A HYBRID ACTIVE POWER FILTER OPERATING OVER A VARIABLE FREQUENCY

(71) Applicant: Hamilton Sundstrand Corporation, Charlotte, NC (US)

(72) Inventor: Fernando Rodriguez, Manchester, CT (US)

(21) Appl. No.: 13/923,708

(22) Filed: Jun. 21, 2013

(51) Int. Cl. G01R 27/26

(52) U.S. Cl. CPC G01R 27/2611
USPC 324/602; 324/654

(57) ABSTRACT

Embodiments relate to systems and methods for selecting circuit element values for a hybrid active power filter operating over a variable frequency. In aspects, a hybrid active power filter (HAPF) circuit can eliminate current harmonics present in an AC power source which are caused by an AC load network.—In implementations, the AC voltage source—may be a source having a variable frequency range, for instance 360-800 Hz. Since the source voltage can encompass a significant frequency range, a simple determination of the correct or desirable values of capacitive and inductive elements in the filtering section of the HAPF may not be possible. According to aspects, analytic techniques are provided which allow the values of those circuit elements to be derived from impedance and other circuit values to provide satisfactory suppression of identified harmonics, which can include the 5^{th}, 7^{th}, 11^{th}, 13^{th}, 17^{th}, 19^{th}, 23^{rd}, 25^{th} harmonics in the output voltage.

### FIELD

The present teachings relate to systems and methods for selecting circuit element values for a hybrid active power filter operating over a variable frequency, and more particularly, to platforms and techniques for identifying necessary values of circuit components to permit a hybrid active power filter to operate over a desired variable frequency range.

### BACKGROUND

In the field of power systems, it has been known to connect a rectifier to an alternating current (AC) power source to derive a direct current (DC) for motors or other loads. A rectifier connected to a 3-phase AC voltage source, however, generates undesired current harmonics, namely the 5th, 7th, 11th, 13th, 17th, 19th, 23rd, and 25th harmonics, which can introduce noise and other artifacts in the power circuit.

To address that undesirable harmonic content, it has been known to use a shunt active power filter, as shown in FIG. 1. A shunt active power filter, however suffers from the drawback of requiring a high dc link voltage (Vdc>Vs, peak), as well as a high switching frequency.

A hybrid active power filter can also be used eliminate the undesirable harmonics, with the added benefit of using a lower dc link voltage (0.15*Vs, peak<Vdc<0.35Vs, peak). In a HAPF circuit, the lower voltage is made possible because the filter capacitor (Cf) acts to block the fundamental voltage component. Use of an HAPF has been demonstrated and documented for fixed frequencies (50 and 60Hz) in known designs.

Nevertheless, the application of an HAPF system to a variable frequency system has not been demonstrated. In an HAPF system designed to operate on source voltages which are variable, such as between 360-800 Hz, the selection of the values for constituent capacitors and filter inductors becomes important to ensure reliable and effective operation.

### DESCRIPTION OF DRAWINGS

The accompanying drawings, which are incorporated in and constitute a part of this specification, illustrate embodiments of the present teachings and together with the description, serve to explain the principles of the present teachings. In the figures:

FIG. 1 illustrates an exemplary shunt active power filter, according to known implementations;

FIG. 2 illustrates an exemplary HAPF circuit, according to various embodiments of the present teachings; a

FIG. 3 illustrates a graph of harmonic amplitudes versus AC impedance (Lac) values, according to various embodiments; and

FIG. 4 illustrates a graph of filter impedance versus current in various logarithmic ranges, according to various embodiments of the present teachings.

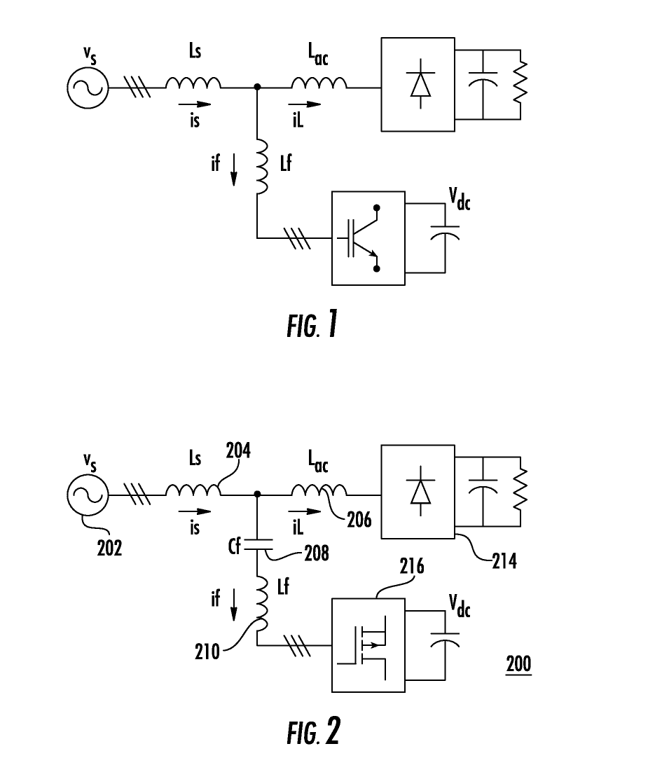

### DESCRIPTION OF EMBODIMENTS

Embodiments of the present teachings relate to systems and methods for selecting circuit element values for a hybrid active power filter operating over a variable frequency. More particularly, embodiments relate to platforms and techniques for identifying or selecting capacitor and inductor values which permit the suppression of undesired harmonics, even while operating over a significant range of variable input frequency.

Reference will now be made in detail to exemplary embodiments of the present teachings, which are illustrated in the accompanying drawings. Where possible the same reference numbers will be used throughout the drawings to refer to the same or like parts.

FIG. 2 illustrates an exemplary HAPF circuit 200 in which systems and methods for selecting circuit element values for a hybrid active power filter operating over a variable frequency can operate, according to aspects. In aspects as shown, the HAPF circuit 200 can contain a voltage source 202, which can be or include an AC current source. In implementations, the voltage source 202 can be a three-phase current source. In implementations, the current source can be configured to provide an AC power signal over a range of AC frequencies. In one implementation, the range of AC frequencies can be, for instance, 360-800 Hz, but it will be appreciated that other frequency ranges for the voltage source 202 can be employed.

The HAPF circuit 200 can likewise include an inductor 204 through which a source current flows, which is delivered to remaining elements of the HAPF circuit 200. In one branch of the circuit topology, a portion of the source current (iL) can be delivered to an inductor 206 and a network 214. The inductor 206 can function to provide an inductive load on the portion of the incoming AC source current which is delivered to the network 214. In implementations as shown, the network 214 can contain a diode element as well as a parallel capacitor-resistor network.

In aspects, a portion of the source current (if) can also be delivered to a set of other circuit elements including capacitor 208, inductor 210, and network 216. In implementations as shown, the network 216 can include a transistor or other switching element, along with a capacitor across which the DC voltage output of the HAPF circuit 200 is delivered. According to aspects, the present teachings provide an analytical method for calculating the values of capacitor 208 (labeled Cf) and inductor 210 (labeled Lf) in the HAPF 200, to permit satisfactory operation over a source frequency range of at least 360 Hz-800 Hz, or others. One objective of that analysis is to choose the values of the inductor 206 (labeled Lac) inductor 210, and capacitor 208 to inject harmonics while using 200V MOSFET transistor elements (Vs can be 400VLL). In instances where the exact type or design of inductor 206 is available, then that information can be used to set the harmonic amplitudes. In instances where that information is not known, for a given inductor 206, the harmonic values can be located through analytical expressions or simulation.

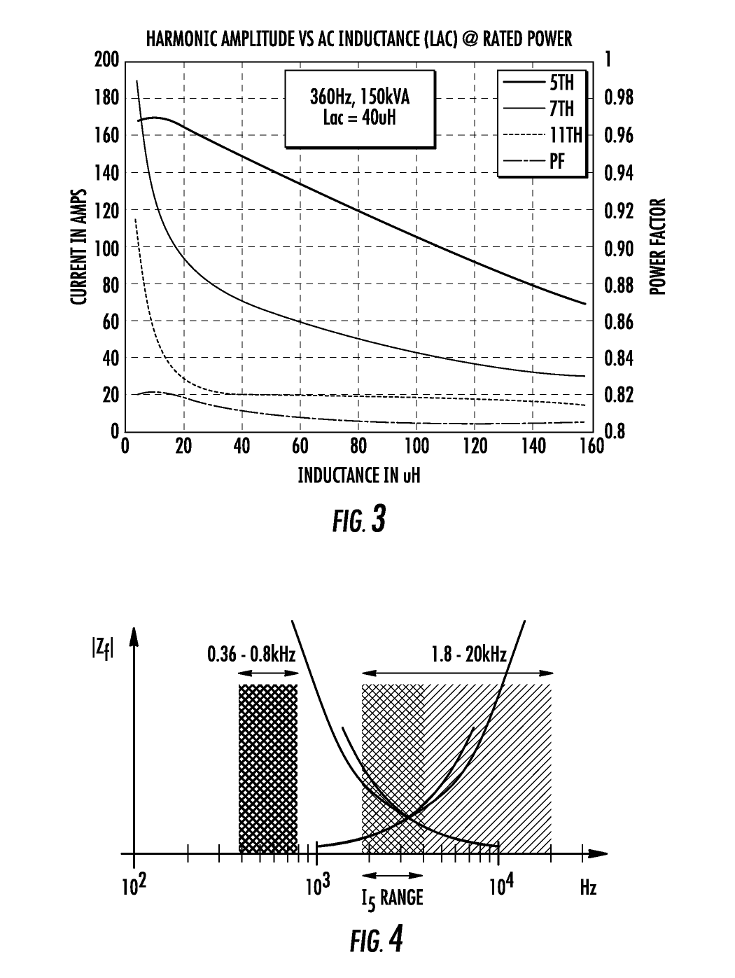

More particularly, the analysis can start with a value for the inductor 206. That value determines the amplitude of undesired harmonics. In particular, a higher value of inductance for the inductor 206 results in a lower value for harmonic current values, as for instance shown in FIG. 3. The value for the amplitudes of harmonic currents at the fifth harmonic frequencies (5*360 Hz-5*800 Hz) are known via simulation, as again shown in FIG. 3.

With those parameters established, according to aspects, the choice of capacitance value for capacitor 208 and inductance value for inductor 210 must result in the following properties:
a small reactive fundamental current (block fundamental current component)
a low |Zf (ω)| to allow for current harmonic injection with 200V MOSFETS; and
since the 5th harmonic current has greatest magnitude, the |Zf (ω)| must be low over the 5th harmonic when the frequency varies from 360-800 Hz. A graph of this further condition is illustrated, for instance, in FIG. 4.

With those conditions in view, the following quantities can be determined. Equations 1-3 are used to calculate the value of the capacitance value of capacitor 208 and the inductance value of inductor 210. Equations 4 and 5 are a result of equations 1-3, and Equations 4 and 5 can be re-arranged to produce Equations 6 and 7. Equations 6 and 7 can be used to explicitly solve for the values of the capacitor 208 and inductor 210. It may be noted that Equations 6 and 7 assume a resonant frequency between 5*360 and 5*800 Hz, reflecting the fifth harmonic of the source current caused by the network 214. The resulting values allow the HAPF to satisfactory reduce all harmonics of interest, including the 5^{th}, 7^{th}, 11^{th}, 13^{th}, 17^{th}, 19^{th}23^{rd}, 25^{th} harmonics, over the entire illustrative target range of 360-800 Hz.

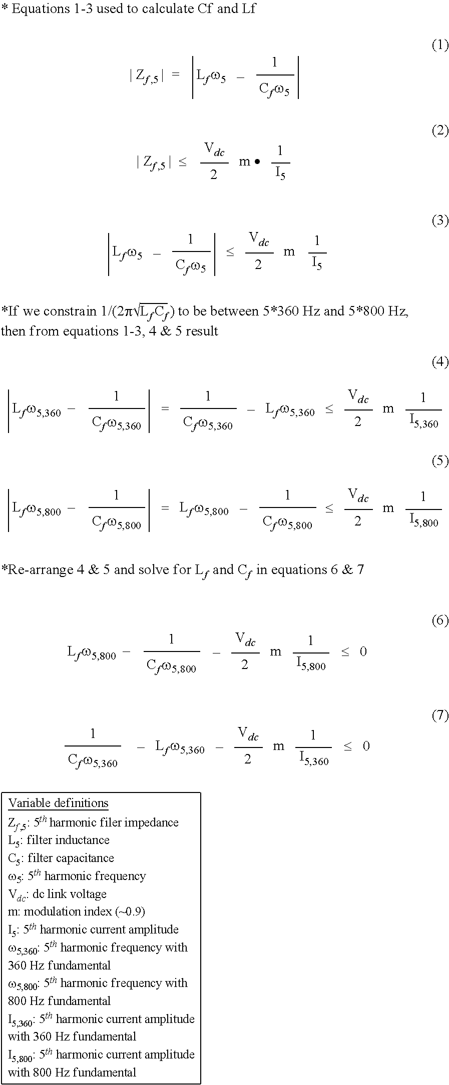

The foregoing description is illustrative, and variations in configuration and implementation may occur to persons skilled in the art. For example, while embodiments have been described in which a single network 214 and single network 216 are provided in the HAPF circuit 200, in implementations, multiple networks providing similar circuit functionality can be provided. Other resources described as singular or integrated can in embodiments be plural or distributed, and resources described as multiple or distributed can in embodiments be combined. Other circuit elements or topologies can be used in the HAPF circuit 200 to provide filtered power while adhering to the same approach to selection of capacitive and inductive values described above. The scope of the present teachings is accordingly intended to be limited only by the following claims.

What is claimed is:

1. A method of generating circuit element values in a hybrid active power filter, comprising:
determining a value of an inductive load provided to a source alternating current;
identifying a variable frequency range of the source alternating current;
determining an amplitude of a set of current harmonics related to the source alternating current over the variable frequency range;
generating at least an inductor value and a capacitor value for a filter network provided in an output stage based on an impedance of the filter network configured to reduce the amplitude of the set of current harmonics.

2. The method of claim 1, wherein the variable frequency range of the source alternating current comprises a range of at least 360 Hz to 800 Hz.

3. The method of claim 1, wherein the set of current harmonics related to the source alternating current comprises at least a set of 5^{th}, 7^{th}, 11^{th}, 19^{th}, 23^{rd}, and 25 harmonics.

4. The method of claim 3, wherein the impedance of the filter network is based on an amplitude of the 5^{th} current harmonic over the variable frequency range.

5. The method of claim 1, wherein the impedance of the filter network is selected to allow use of metal oxide semiconductor field effect transistors (MOSFETs) for current harmonic injection at a rated voltage.

6. The method of claim 5, wherein the MOSFETs rated voltage is 200 V.

7. The method of claim 1, wherein generating at least an inductor value and a capacitor value comprises solving: [insert of Equations 6 and 7].

8. The method of claim 1, wherein determining the value of the inductive load comprises performing a simulation.

9. The method of claim 1, wherein determining the amplitude of the set of current harmonics comprises performing a simulation.

10. The method of claim 1, wherein performing a simulation comprises performing a simulation at—frequencies of 360-800 Hz.
